(19) United States
(12) Patent Application Publication
(10) Pub. No.: US 2025/0068538 A1
(43) Pub. Date: Feb. 27, 2025

(54) TIME DOMAIN PERFORMANCE TESTING FOR DIGITAL DEVICES

(71) Applicant: STMicroelectronics International N.V., Geneva (CH)

(72) Inventors: Sharad GUPTA, New Delhi (IN); Ankur BAL, Greater Noida (IN)

(21) Appl. No.: 18/766,904

(22) Filed: Jul. 9, 2024

Related U.S. Application Data
(60) Provisional application No. 63/578,426, filed on Aug. 24, 2023.

(51) Int. Cl. G06F 11/34; G01R 31/28; G06F 11/30

(52) U.S. Cl. CPC G06F 11/3419; G01R 31/2837; G01R 31/2843; G06F 11/3024

(57) ABSTRACT

Various embodiments of the present disclosure disclose improved BIST systems and methods for testing digital devices. A method for testing a digital device includes receiving, based at least in part on an input signal, an output signal from a device under testing (DUT). The output signal is processed to generate a noise signal and a recovered signal for the DUT. The controller may generate a signal to noise power ratio based at least in part on the noise and recovered signals and compare the signal to noise power ratio to a predetermined power threshold to generate a performance metric.

### CROSS-REFERENCE TO RELATED APPLICATIONS

This application claims priority to, and the benefit of, U.S. Provisional patent application Ser. No. 63/578,426, filed Aug. 24, 2023 and entitled “Time Domain Performance Testing for Digital Devices,” the entire disclosure of which is hereby incorporated herein by reference in its entirety for all purposes.

### TECHNOLOGICAL FIELD

Example embodiments of the present disclosure relate generally to the phase-independent testing of a digital device, and in particular, to built-in testing for continuous time digital devices, such as continuous-time sigma-delta converters.

### BACKGROUND

Applicant has identified many technical challenges and difficulties associated with testing mixed-signal intellectual property (IP) core systems. Through applied effort, ingenuity, and innovation, Applicant has solved problems related to traditional automated test equipment (ATE), as well as other performance limitations of traditional testing techniques, by developing solutions embodied in the present disclosure, which are described in detail below.

### BRIEF SUMMARY

Various embodiments described herein relate to systems, apparatuses, products, and methods for testing complex systems.

In some embodiments, a controller is configured to receive, based at least in part on an input signal, an output signal from a device under testing (DUT); generate a noise signal based at least in part on the input signal and the output signal; generate a recovered signal based at least in part on the output signal and the noise signal; generate a signal to noise power ratio based at least in part on the recovered signal and the noise signal; and generate a performance metric for the DUT based at least in part on a comparison between the signal to noise power ratio and a predetermined power threshold.

In some examples, the performance metric is a signal to noise (SNR) metric.

In some examples, the predetermined power threshold is one of a plurality of predetermined power thresholds that are stored in a lookup table and each of the plurality of predetermined power thresholds are indicative of a respective threshold SNR metric.

In some examples, generating the signal to noise power ratio includes generating, using a first power accumulator, a signal power based at least in part on the recovered signal; generating, using a second power accumulator, a noise power based at least in part on the noise signal; and generating the signal to noise power ratio based at least in part on the signal power and the noise power.

In some examples, generating the noise signal includes extracting, using a notch infinite impulse response (IIR) filter, the noise signal from the output signal.

In some examples, generating the recovered signal includes subtracting the noise signal from the output signal.

In some examples, the recovered signal and the noise signal are accumulated for a 1024 sample.

In some examples, the controller is configured to output the performance metric.

In some examples, the input signal is a sinusoid and the controller is further configured to generate the input signal by at least generating a modulated pulse; and filtering the modulated pulse to generate the sinusoid.

In some examples, the controller and the DUT are part of the same mixed-signal system and the controller is configured to test the DUT without external control.

In some examples, the DUT is a continuous-time sigma-delta analog to digital converter.

In some embodiments, the method includes receiving, based at least in part on an input signal, an output signal from a device under testing (DUT); generating a noise signal based at least in part on the input signal and the output signal; generating a recovered signal based at least in part on the output signal and the noise signal; generating a signal to noise power ratio based at least in part on the recovered signal and the noise signal; and generating a performance metric for the DUT based at least in part on a comparison between the signal to noise power ratio and a predetermined power threshold.

In some examples, the performance metric is a signal to noise (SNR) metric.

In some examples, the predetermined power threshold is one of a plurality of predetermined power thresholds that are stored in a lookup table and each of the plurality of predetermined power thresholds are indicative of a respective threshold SNR metric.

In some examples, generating the signal to noise power ratio includes generating, using a first power accumulator, a signal power based at least in part on the recovered signal; generating, using a second power accumulator, a noise power based at least in part on the noise signal; and generating the signal to noise power ratio based at least in part on the signal power and the noise power.

In some examples, generating the noise signal includes extracting, using a notch infinite impulse response (IIR) filter, the noise signal from the output signal.

In some embodiments, a system includes a device under testing (DUT); and a controller. The controller is configured to receive, based at least in part on an input signal, an output signal from the DUT; generate a noise signal based at least in part on the input signal and the output signal; generate a recovered signal based at least in part on the output signal and the noise signal; generate a signal to noise power ratio based at least in part on the recovered signal and the noise signal; and generate a performance metric for the DUT based at least in part on a comparison between the signal to noise power ratio and a predetermined power threshold.

In some examples, the DUT is a continuous-time sigma-delta analog to digital converter.

In some examples, the input signal is a sinusoid and the controller is further configured to generate the input signal by at least generating a modulated pulse; and filtering the modulated pulse to generate the sinusoid.

In some examples, the system is a system on a chip (SoC) or a system in a package (SiP).

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF SUMMARY OF THE DRAWINGS

Having thus described certain example embodiments of the present disclosure in general terms, reference will now be made to the accompanying drawings, which are not necessarily drawn to scale, and wherein:

FIG. 1 illustrates an example computing ecosystem in accordance with one or more embodiments of the present disclosure;

FIG. 2 illustrates a block diagram of a built-in self-test (BIST) system in accordance with one or more embodiments of the present disclosure;

FIG. 3 illustrates a block diagram of an example signal and noise separator in accordance with one or more embodiments of the present disclosure;

FIG. 4 illustrates a dataflow diagram of an example signal and noise separator in accordance with one or more embodiments of the present disclosure;

FIG. 5 illustrates a circuit diagram of an example notch filter in accordance with one or more embodiments of the present disclosure;

FIG. 6 illustrates a dataflow diagram of an example performance measurement process in accordance with one or more embodiments of the present disclosure;

FIG. 7 illustrates a circuit diagram of an example performance measurement process in accordance with one or more embodiments of the present disclosure;

FIG. 8 illustrates a flowchart of an example method for testing a digital device in accordance with one or more embodiments of the present disclosure.

### DETAILED DESCRIPTION

Embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

Various example embodiments of the present disclosure are directed to improved testing devices and systems, apparatuses, products, and methods for testing digital devices. The present disclosure, in some examples, describes a BIST system that is tailored for testing intellectual property (IP) cores, complex systems on a chip (SoCs) and system in a package (SiPs), to improve upon traditional testing techniques that are unable to calculate performance metrics is a time domain.

For example, traditional testing for mixed-signal IP cores relies on functional specification testing that uses specialized automated test equipment (ATE) for applying appropriate test stimuli, retrieving the output responses, and processing the test results. However, in a complex SoC/SiP architectures—where the external access to the internal IPs is difficult, or directly impossible—these operations are challenging, cost prohibitive, and fail to evaluate the performance of a digital devices, such as analog to digital converters (ADCs), in continuous time. High Performance Continuous Time Sigma Delta ADC testing involves application of clean analog input signal to a device under testing (DUT) and analyses of the measured signal. Traditional techniques require that the phase of the reference and the measured signals are aligned, which presents a number of technical disadvantages for evaluating continuous time devices, such as continuous time sigma delta modulators, that have unpredictable phase shifts. In such a case, sine wave fitting may not be possible as the phase of the test signal may be unknown. Other techniques may be implemented to perform phase independent testing for digital devices. However, such techniques rely on bin power computations in a frequency domain, which may be time consuming to generate and may rely on a plurality of bin specific variables. Some embodiments of the present disclosure overcome these technical problems by enabling a phase independent signal analysis in the time domain.

Some embodiments of the present disclosure, provide a complete on-chip architecture for testing of Continuous Time Sigma Delta ADC. In some examples, the architecture may provide an input signal that is smoothened by a linear finite impulse response (FIR) digital to analog converter (DAC) filter and applied to a DUT. In this way, a full dynamic range signal may be ensured at the DUT. The output signal of the DUT may be evaluated by a testing controller, using some of the techniques of the present disclosure, to extract the performance of the DUT. For instance, a noise signal may be generated based at least in part on the input signal and the output signal, a recovered signal may be generated based at least in part on the output signal and the noise signal, a noise power ratio may be generated based at least in part on a comparison between the recovered and noise signals, and a performance metric may be generated for the DUT based at least in part on the comparison between the signal to noise power ratio and a predetermined power threshold. In this way, a testing device and method of testing a digital device may be provided that is suitable for all types of converter (e.g., ADC, etc.) testing, has less turnaround time (e.g., less than 2500 samples), is scalable for higher performance modulators, has a low area digital analyzer (e.g., <350 FFs for 12b ENOB 40 MSPS data), and matches actual performance requirements, The testing device and method of testing a digital device may present a new and efficient solution by using a time domain computation of an output bitstream of a digital device to calculate a performance metric, such as signal-to-noise ratio (SNR), in a time domain.

It should be readily appreciated that the embodiments of the systems, apparatus, and methods described herein may be configured in various additional and alternative manners in addition to those expressly described herein.

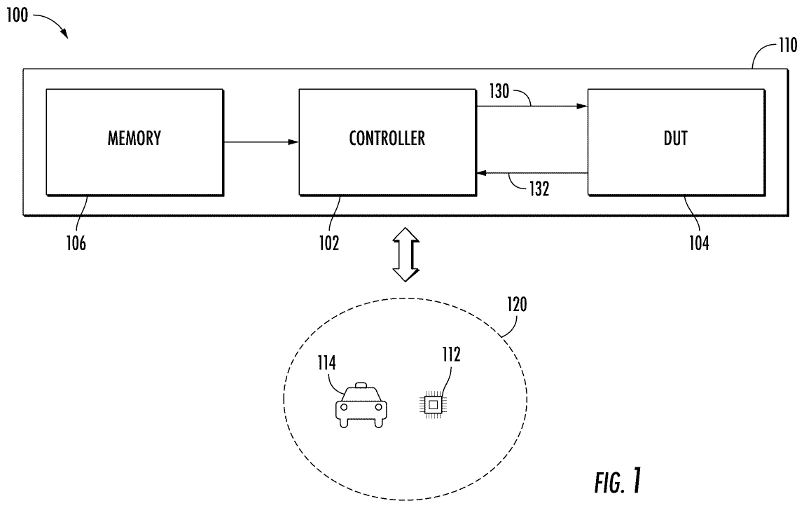

FIG. 1 illustrates an example computing ecosystem 100 in accordance with one or more embodiments of the present disclosure. In general, the terms computing system, computer, system, device, entity, and/or similar words used herein interchangeably may refer to, for example, one or more BIST systems, computers, computing entities, desktops, mobile phones, tablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes may be performed on data, content, information, and/or similar terms used herein interchangeably.

The computing ecosystem 100 may include a BIST system 110 and/or one or more computing entities 120 that may be integrated with the BIST system 110. For example, the BIST system 110 may include a controller 102, a DUT 104, and/or a memory 106. The controller 102 may be communicably coupled to the DUT 104 and/or the memory 106. The BIST system 110 may be an SOC), an SIP, and/or may be part of the SOC, SIP, and/or the like. For instance, the BIST system 110 may include a part of an integrated circuit 112, an advanced driver-assistance system 114, and/or any other analog to digital system configured to convert one or more analog signals to a digital output and/or vice versa.

In some embodiments, the BIST system 110 includes one or more mixed-signal IP cores in which access to a core is restricted. For example, access to the DUT 104 may be restricted by a design of a core. The controller 102 or another device of the computing ecosystem 100 may be configured with a BIST and may perform the test (as an on-system test) on the DUT 104 thereby forgoing a dedicated external test.

The DUT 104 may be a modulator or a converter, such as a continuous-time sigma-delta analog to digital converter (ADC), among others. The DUT 104 may receive a first signal that is a continuous-time analog signal and output a second signal that is a digital representative of the first signal. The BIST may determine a performance metric for the DUT 104. The performance metric may represent or reflect the performance of the DUT 104 in response to a stimulus. The performance metric may be an SNR metric and/or a total harmonic distortion of the DUT 104.

The memory 106 may be any data storage device. The memory 106 may store executable instructions that, when executed by the controller 102, cause the controller 102 to operate as described herein. The memory 106 may be read-only memory (ROM) or random access memory (RAM), among others. In addition to executable instructions, the memory 106 may store data. The data may include results of tests performed on the DUT 104.

The controller 102 may be any device configured to test the DUT 104. The controller 102 may include, or be in communication with, one or more processing elements (also referred to as processors, processing circuitry, digital circuitry, and/or similar terms used herein interchangeably) that may be embodied in a number of different ways. For example, the processing elements may be embodied as one or more complex programmable logic devices (CPLDs), microprocessors, multi-core processors, coprocessing entities, application-specific instruction-set processors (ASIPs), microcontrollers, and/or the like. Further, a processing element may be embodied as one or more other processing devices or circuitry. The term circuitry can refer to an entirely hardware embodiment or a combination of hardware and computer program products. Thus, the processing element may be embodied as integrated circuits, application specific integrated circuits (ASICs), field programmable gate arrays (FPGAs), programmable logic arrays (PLAs), hardware accelerators, digital circuitry, and/or the like.

As will therefore be understood, the controller 102 may be configured for a particular use or configured to execute instructions stored in memory 106 or otherwise accessible to the controller 102. As such, whether configured by hardware or non-transitory computer readable media, or by a combination thereof, the controller 102 may be capable of performing steps or operations according to embodiments of the present disclosure when configured accordingly.

In some embodiments, the controller 102 generates and sends an input signal 130 to the DUT 104. In response to sending the input signal 130, the controller 102 may receive an output signal 132 from the DUT 104. The controller 102 may evaluate the output signal 132 to determine a performance metric for the DUT 104. For example, the controller 102 may determine an SNR for the DUT 104, a harmonic distortion, or another signal quality indicator.

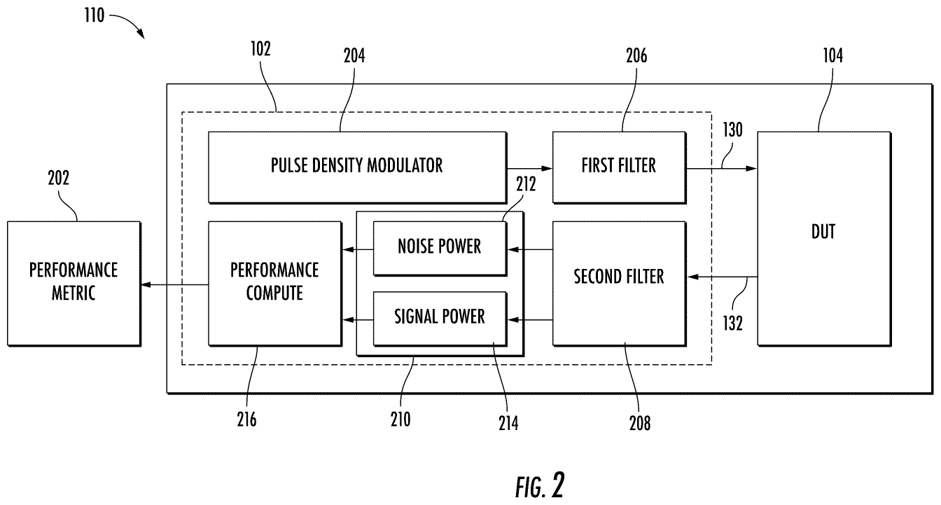

Example embodiments of the present disclosure describe an improved BIST system that may be integrated within a complex system to test the performance of one or more digital devices within the complex system, such as the DUT 104. The digital devices may be tested using one or testing techniques as described with reference to FIG. 2.

FIG. 2 illustrates a block diagram of a BIST system 110 in accordance with one or more embodiments of the present disclosure. In some embodiments, the BIST system 110 includes a controller 102 and/or a DUT 104. In some examples, the BIST system 110 may be and/or be integrated with an SoC and/or SiP. In some examples, the controller 102 and the DUT 104 may be part of the same mixed-signal system and the controller 102 may test (e.g., using some of the techniques described herein) the DUT 104 without external control. For example, the controller 102 may provide an input signal 130 to the DUT 104 and receive, based at least in part on the input signal 130, an output signal 132 from the DUT 104. The controller 102 may process the output signal 132 to generate a performance metric 202 for the DUT 104.

In some embodiments, the controller 102 includes a pulse density modulator 204, a first filter 206, a second filter 208, a power ratio compute 210 configured to generate a noise power 212 and/or a signal power 214, and/or a performance compute 216 configured to generate a performance metric 202 based at least in part on the noise power 212 and/or the signal power 214. The controller 102, for example, may include an output port coupled to an input port of the DUT 104 and/or an input port coupled to an output port of the DUT 104. The pulse density modulator 204 may include any type of modulator, including a one-bit ROM, and/or the like, configured to generate a modulated signal representative of an analog signal in a digital domain. The signal may be a sinusoid, among others, having a frequency.

In some embodiments, the input signal 130 is a sinusoid and the controller 102 is configured to generate the input signal 130 by at least generating a modulated pulse, using the pulse density modulator 204, and filtering the modulated pulse, using the first filter 206, to generate the sinusoid. The pulse density modulator 204, for example, may output the signal to the first filter 206. The first filter 206 may be a finite impulse response (FIR) digital-to-analog converter (DAC). The first filter 206 may be a low-pass filter. The first filter 206 may be configured to filter and smoothen the signal and output an input signal 130 to the DUT 104. The input signal 130 may be an analog signal (e.g., sinusoid, etc.). The DUT 104 may receive the input signal 130, process the input signal 130, and output the output signal 132 based at least in part on the input signal 130.

In some embodiments, the DUT 104 generates the output signal 132 based at least in part on the input signal 130. For example, the DUT 104 may include a digital converter circuit, such as an ADC circuit. The DUT 104, for example, may include any type of ADC circuit. In some examples, the DUT 104 may include a continuous-time sigma-delta ADC (CTSDM) configured to convert an analog signal over a wide range of frequencies. The DUT 104, for example, may include an oversampling modulator followed by a digital/decimation filter configured to convert an analog signal, such as the input signal 130, to a high-resolution data-stream output, such as the output signal 132. The output signal 132, for example, may be a digital signal having undergone digitization by the DUT 104.

In some embodiments, the DUT 104 outputs the output signal 132 to the controller 102. The output signal 132 may have a phase shift in relation to the input signal 130. As described herein, the controller 102 may be configured to generate a phase-agnostic performance metric, whereby the phase shift of the output signal due to operation of the DUT 104 may not be known and does not materially impact the performance metric 202 for the DUT 104. The second filter 208 of the controller 102 may receive the output signal 132 and filters the output signal 132 to generate a filtered signal. The second filter 208, for example, may reduce the rate of the output signal 132.

In some embodiments, the controller 102 includes a power ratio compute 210 that receives the output signal 132 (and/or the filtered output signal). The power ratio compute 210 may include circuitry configured to generate a noise signal and a recovered signal from the output signal 132. In some embodiments, the power ratio compute 210 includes one or more power accumulators configured to transform the noise signal and/or the recovered signal to a noise power 212 and/or a signal power 214, respectively.

In some embodiments, the controller 102 includes a performance compute 216 that receives the noise power 212 and the signal power 214 (and/or a ratio thereof). The performance compute 216 may include circuitry configured to generate a performance metric 202 based at least in part on a comparison of the noise power 212, the signal power 214, and/or one or more predetermined thresholds. As described herein, the noise power 212 and the signal power 214 may be provided to a performance compute 216 to generate a performance metric 202.

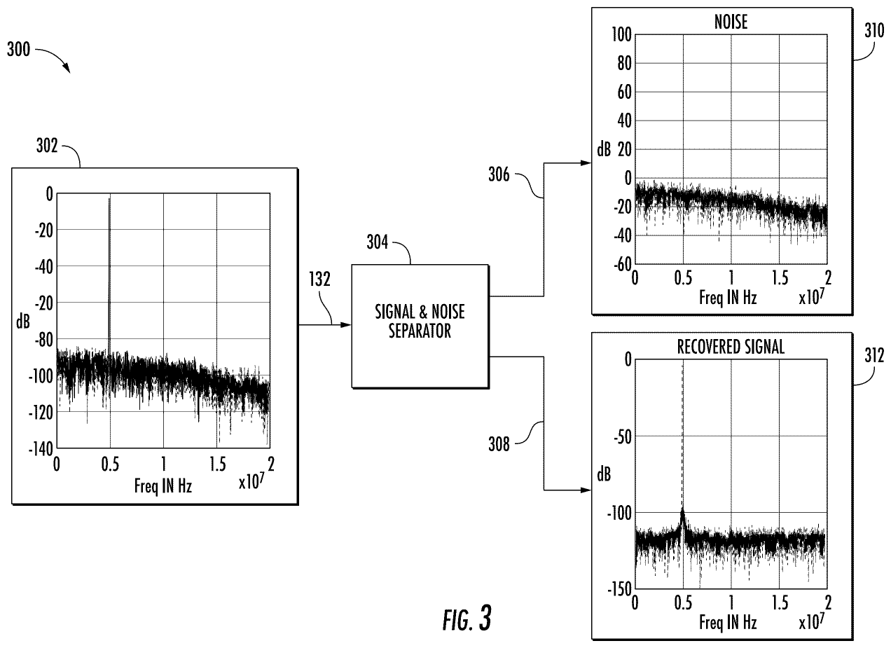

In this manner, a performance metric 202 may be generated for a DUT 104 by separating a noise signal from a recovered signal, generating a power ratio based at least in part on the noise and recovered signals, and comparing the ratio to a predetermined threshold. Each operation may be performed by the controller 102 and/or specialized circuitry of the controller 102. By way of example, a noise and recovered signal may be generated by signal and noise separator, which is further described with reference to FIG. 3.

FIG. 3 illustrates a block diagram 300 of an example signal and noise separator in accordance with one or more embodiments of the present disclosure. The block diagram 300 includes an output signal representation 302 for an output signal 132. The output signal 132 is provided to the signal and noise separator 304. The signal and noise separator 304 may include circuitry specially configured to separate a noise signal 306 and a recovered signal 308 from the output signal 132. In this manner, the controller, using the signal and noise separator 304, generates a noise signal 306, as represented by the noise signal representation 310, and/or a recovered signal 308, as represented by the recovered signal representation 312, based at least in part on the output signal 132.

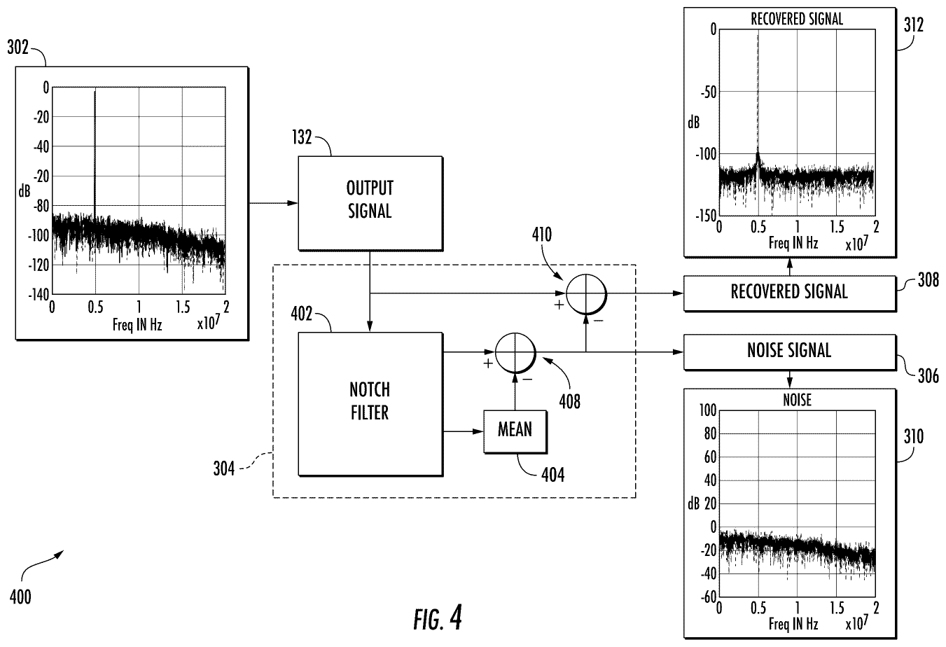

The signal and noise separator 304 may include circuitry specially configured to generate the noise signal 306 and the recovered signal 308 in accordance with one or more signal processing operations described with reference to FIG. 4.

FIG. 4 illustrates a dataflow diagram 400 of an example signal and noise separator in accordance with one or more embodiments of the present disclosure. The signal and noise separator 304 may be configured to receive an output signal 132, as represented by the output signal representation 302, and output a recovered signal 308, as represented by the recovered signal representation 312, and/or a noise signal 306, as represented by the noise signal representation 310. The signal and noise separator 304 may include a notch filter 420, a first electrical connector 408, and/or a second electrical connectors 410. The output signal 132, for example, may include a decimated signal (e.g., sinusoid+noise) output (e.g., at fs=40 MHz, fIN=5 MHz) from a DUT based at least in part on an input signal.

In some embodiments, the controller generates the noise signal 306 based at least in part on an input signal and the output signal 132. For example, the notch filter 402 may be configured based at least in part on the input signal to extract the noise signal 306 from the output signal 132. The notch filter 402 may include any type of notch filter circuit. In some examples, the notch filter 402 may include a notch infinite impulse response (IIR) filter specially configured for a specific input signal. In some embodiments, the controller extracts, using the notch IIR filter, the noise signal 306 from the output signal 132. The output signal 132, for example, may be provided to the notch filter 402 to receive the noise signal 306. In some examples, the notch filter 402 may generate an average noise signal 404 for at least 1024 cycles. The average noise signal 404 may be compared, at the first electrical connector 408, to an extracted signal to generate the noise signal 306 from the output signal 132.

In some embodiments, the controller generates the recovered signal 308 based at least in part on the output signal 132 and the noise signal 306. In some embodiments, the controller subtracts the noise signal 306 from the output signal 132 to generate the recovered signal 308. For example, at the second electrical connector 410, the noise signal 306 may be removed from the output signal 132 to generate the recovered signal 308.

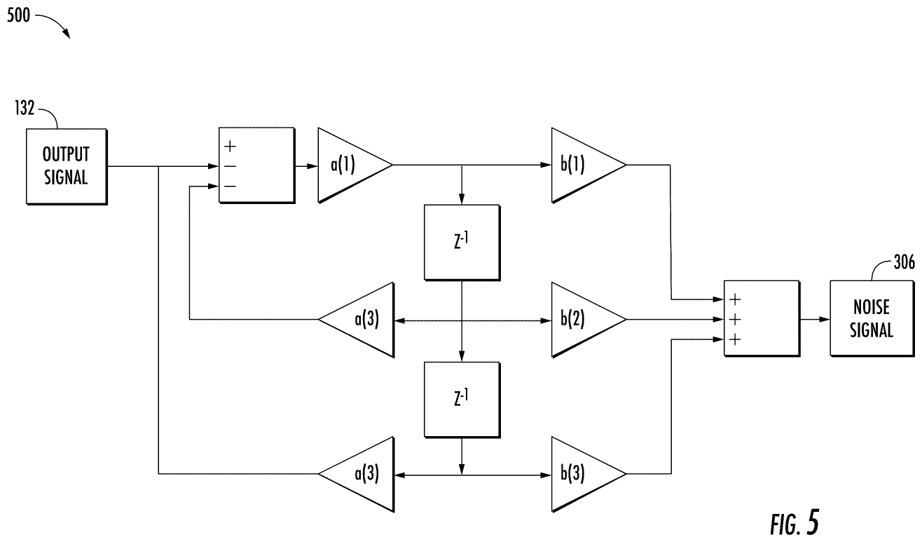

The notch filter 402 may include circuitry specially configured to generate the noise signal 306 as described with reference to FIG. 5.

FIG. 5 illustrates a circuit diagram 500 of an example notch filter design in accordance with one or more embodiments of the present disclosure. The circuit diagram 500 illustrates one example notch filter design for extracting a noise signal 306 from the output signal 132. The notch filter design may form a notch infinite impulse response (IIR) filter that may be configured to extract the noise signal in accordance with the following:

$$H ( z ) = \frac{1 - 2 cos ( \frac{fo}{f s} ) * {z}^{- 1} + {z}^{- 2}}{1 - 2 * r * cos ( \frac{fo}{f s} ) * {z}^{- 1} + {r}^{2} * {z}^{- 2}}$$

where F0 may equal 5 MHZ, Fₛ may equal 40 MHz, and/or Q may equal 50.

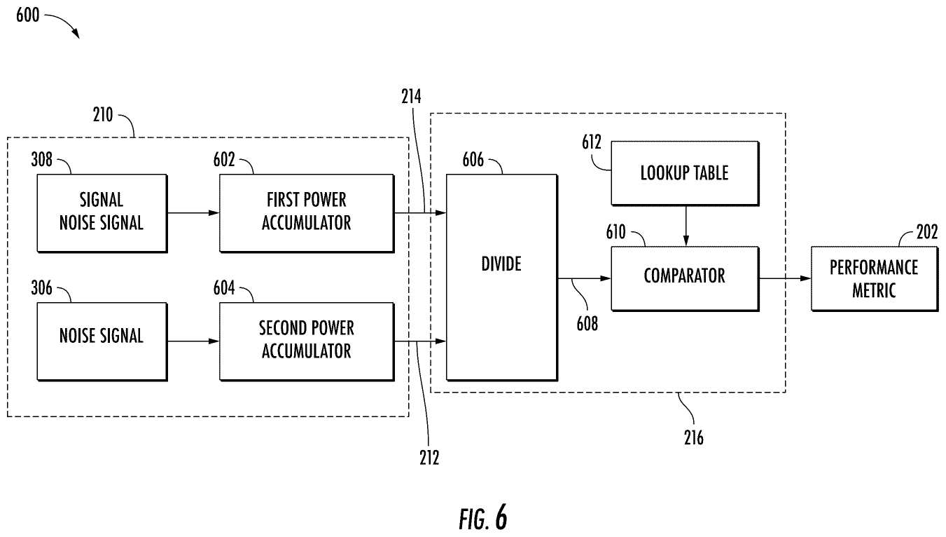

In some embodiments, the noise signal 306 (and/or the recovered signal described herein) may be provided to one or more power accumulators to generate a noise and signal power. The noise and signal power may be leveraged to generate a performance metric in accordance with one or more performance measurement operations described with reference to FIG. 6.

FIG. 6 illustrates a dataflow diagram 600 of an example performance measurement process in accordance with one or more embodiments of the present disclosure. The performance measurement process may be performed by the controller and/or one or more circuitry thereof. For instance, the controller may include a power ratio compute 210 that may be configured to generate the recovered signal 308 and the noise signal 306 (e.g., using the noise and signal separator, etc.) and output the noise power 212 and the signal power 214. The noise power 212 and/or the signal power may be output to the performance compute 216, which may be configured to generate the performance metric 202 based at least in part on the noise power 212 and the signal power 214.

In some embodiments, the controller generates a signal to noise power ratio 608 based at least in part on the recovered signal 308 and the noise signal 306. For example, the controller may generate, using a first power accumulator 602, a signal power 214 based at least in part on the recovered signal 308. The signal power 214 may be a power measurement that is indicative of an energy signature of the recovered signal 308. The controller may generate, using a second power accumulator 604, a noise power 212 based at least in part on the noise signal 306. The noise power 212 may be another power measurement that is indicative of an energy signature of the noise signal 306.

The controller may generate the signal to noise power ratio 608 based at least in part on the signal power 214 and the noise power 212. For instance, the signal power 214 and the noise power 212 may be provided to a division component 606 to generate the signal to noise power ratio 608. The signal to noise power ratio 608, for example, may include a measurement that is indicative of the signal power 214 divided by the noise power 212. In some examples, the recovered signal 308 and/or the noise signal 306 may be accumulated for a 1024 sample. For instance, the recovered signal 308 and/or the noise signal 306 may be accumulated for a 1024 sample and then division may be performed to calculate the signal to noise power ratio 608.

In some embodiments, the controller generates a performance metric 202 for the DUT based at least in part on a comparison between the signal to noise power ratio 608 and a plurality of predetermined power thresholds. The plurality of predetermined power thresholds, for example, may be stored in a lookup table 612. Each of the plurality of predetermined power thresholds may be indicative of a respective performance metric. For example, each predetermined power threshold may be indicative of a threshold signal to noise power ratio to achieve a particular performance metric. For instance, the performance metric may include a SNR metric. In such a case, each of the plurality of predetermined power thresholds may be indicative of a respective threshold SNR metric corresponding to each a plurality of different threshold signal to noise power ratios. In some example, the signal to noise power ratio 608 may be provided to a comparator 610 that may compare the signal to noise power ratio 608 with prestored values from the lookup table 612 to generate the performance metric 202, such as an achievable signal to noise ratio for a DUT.

In some embodiments, the controller outputs the performance metric. For example, the controller may initiate the performance of an output of an indication (e.g., a light, display, etc.) of the performance metric. The indication, for example, may include a status indicator (e.g., light, audible sound, etc.) that may be indicative of a relative performance of the DUT with respect to one or more compliance criteria. In addition, or alternatively, the indicator may be indicative of the performance metric, such as an achievable SNR, and/or one or more contributing parameters for the performance metric, such as an output signal representation, a noise signal representation, a recovered signal representation, a signal to noise power ratio, and/or the like.

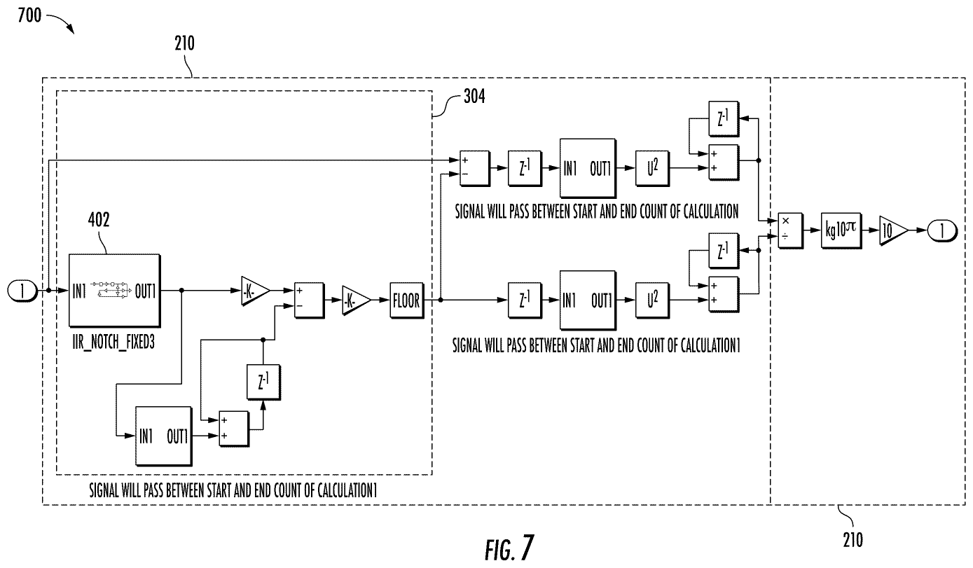

FIG. 7 illustrates a circuit diagram 700 of an example performance measurement process in accordance with one or more embodiments of the present disclosure. The circuit diagram 700 illustrates one example functional circuit representation of the controller circuitry described herein. For example, the circuit representation includes a first portion indicative of the power ratio compute 210 configured to generate the signal to noise power ratio and a second portion indicative of the performance compute 216 configured to generate the performance metric based at least in part on the signal to noise power ratio. The first portion may include a signal and noise separator 304 that is configured to generate, using the notch filter 402, the noise and recovered signals to generate the signal to noise power ratio.

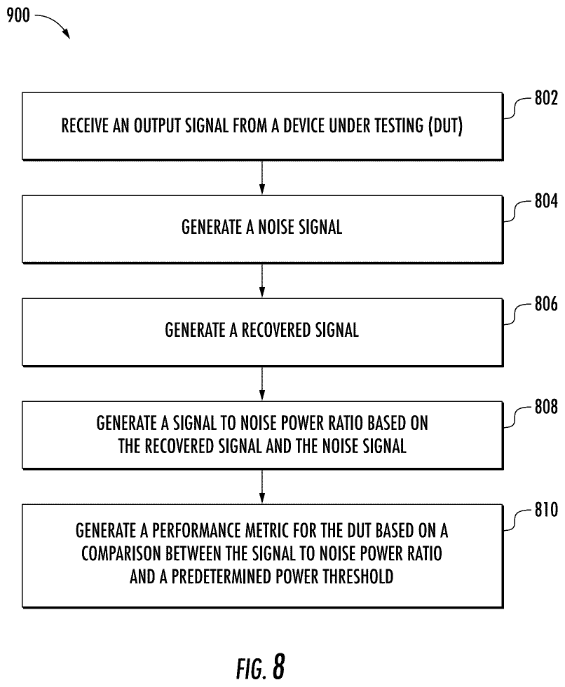

FIG. 8 illustrates a flowchart of an example method 800 for testing a digital device in accordance with one or more embodiments of the present disclosure. The flowchart depicts continuous signal testing techniques for testing the performance of a digital device that overcome various performance limitations of traditional testing techniques. The techniques may be implemented by one or more computing devices, entities, and/or systems described herein. For example, via the various steps/operations of the method 800, a controller, such as the controller 102 described herein, may implement the techniques (e.g., via one or more control instructions, circuitry, and/or the like) to overcome the various limitations with traditional testing techniques by enabling phase independent testing of continuous time signal with at-speed performance testing.

FIG. 8 illustrates an example method 800 for explanatory purposes. Although the example method 800 depicts a particular sequence of steps/operations, the sequence may be altered without departing from the scope of the present disclosure. For example, some of the steps/operations depicted may be performed in parallel or in a different sequence that does not materially impact the function of the method 800. In other examples, different components of an example device or system that implements the method 800 may perform functions at substantially the same time or in a specific sequence.

According to some examples, the method 800 includes, at step/operation 802, receiving an output signal from a DUT. For example, the controller 102 may receive, based at least in part on an input signal, the output signal from the DUT. The input signal, for example, may be a sinusoid and the controller may be configured to generate the input signal by at least generating a modulated pulse and/or filtering the modulated pulse to generate the sinusoid. In some examples, the controller and the DUT may be part of the same mixed-signal system and the controller may test the DUT without external control. In some examples, the DUT may be a continuous-time sigma-delta ADC. In some examples, the controller and the DUT may include and/or be integrated with an SoC and/or SiP.

According to some examples, the method 800 includes, at step/operation 804, generating a noise signal. For example, the controller 102 may generate the noise signal based at least in part on the input signal and the output signal. In some examples, the controller may generate the noise signal by extracting, using a notch IIR filter, the noise signal from the output signal.

According to some examples, the method 800 includes, at step/operation 806, generating a recovered signal. For example, the controller 102 may generate the recovered signal based at least in part on the output signal and the noise signal. In some examples, the controller may generate the recovered signal by subtracting the noise signal from the output signal. In some examples, the recovered signal and the noise signal may be accumulated for a 1024 sample.

According to some examples, the method 800 includes, at step/operation 808, generating a signal to noise power ratio based at least in part on the recovered signal and the noise signal. For example, the controller 102 may generate the signal to noise power ratio based at least in part on the recovered signal and the noise signal. For example, the controller may generate, using a first power accumulator, a signal power based at least in part on the recovered signal and generate, using a second power accumulator, a noise power based at least in part on the noise signal. In some examples, the controller may generate the signal to noise power ratio based at least in part on the signal power and the noise power.

According to some examples, the method 800 includes, at step/operation 810, generating a performance metric for the DUT based at least in part on a comparison between the signal to noise power ratio and a predetermined power threshold. For example, the controller 102 may generate the performance metric for the DUT based at least in part on the comparison between the signal to noise power ratio and the predetermined power threshold. In some examples, the performance metric may be an SNR metric. The predetermined power threshold may be one of a plurality of predetermined power thresholds that are stored in a lookup table. Each of the plurality of predetermined power thresholds may be indicative of a respective threshold SNR metric. In some examples, the controller may output the performance metric.

### CONCLUSION

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. The disclosed embodiments relate primarily to BIST devices and techniques for testing digital devices, however, one skilled in the art may recognize that such principles may be applied to any electrical system. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

While this detailed description has set forth some embodiments of the present disclosure, the appended claims cover other embodiments of the present disclosure which differ from the described embodiments according to various modifications and improvements. For example, the appended claims may cover any form of semiconductor fabrication.

Within the appended claims, unless the specific term “means for” or “step for” is used within a given claim

1. A controller configured to:
receive, based at least in part on an input signal, an output signal from a device under testing (DUT);
generate a noise signal based at least in part on the input signal and the output signal;
generate a recovered signal based at least in part on the output signal and the noise signal;
generate a signal to noise power ratio based at least in part on the recovered signal and the noise signal; and
generate a performance metric for the DUT based at least in part on a comparison between the signal to noise power ratio and a predetermined power threshold.

2. The controller of claim 1, wherein the performance metric is a signal to noise (SNR) metric.

3. The controller of claim 2, wherein the predetermined power threshold is one of a plurality of predetermined power thresholds that are stored in a lookup table and each of the plurality of predetermined power thresholds are indicative of a respective threshold SNR metric.

4. The controller of claim 1, wherein generating the signal to noise power ratio comprises:
generating, using a first power accumulator, a signal power based at least in part on the recovered signal;
generating, using a second power accumulator, a noise power based at least in part on the noise signal; and
generating the signal to noise power ratio based at least in part on the signal power and the noise power.

5. The controller of claim 1, wherein generating the noise signal comprises:
extracting, using a notch infinite impulse response (IIR) filter, the noise signal from the output signal.

6. The controller of claim 1, wherein generating the recovered signal comprises:
subtracting the noise signal from the output signal.

7. The controller of claim 1, wherein the recovered signal and the noise signal are accumulated for a 1024 sample.

8. The controller of claim 1, further configured to:
output the performance metric.

9. The controller of claim 1, wherein the input signal is a sinusoid and the controller is further configured to generate the input signal by at least:
generating a modulated pulse; and
filtering the modulated pulse to generate the sinusoid.

10. The controller of claim 1, wherein the controller and the DUT are part of the same mixed-signal system and the controller is configured to test the DUT without external control.

11. The controller of claim 1, wherein the DUT is a continuous-time sigma-delta analog to digital converter.

12. A method comprising:
receiving, based at least in part on an input signal, an output signal from a device under testing (DUT);
generating a noise signal based at least in part on the input signal and the output signal;
generating a recovered signal based at least in part on the output signal and the noise signal;
generating a signal to noise power ratio based at least in part on the recovered signal and the noise signal; and
generating a performance metric for the DUT based at least in part on a comparison between the signal to noise power ratio and a predetermined power threshold.

13. The method of claim 12, wherein the performance metric is a signal to noise (SNR) metric.

14. The method of claim 13, wherein the predetermined power threshold is one of a plurality of predetermined power thresholds that are stored in a lookup table and each of the plurality of predetermined power thresholds are indicative of a respective threshold SNR metric.

15. The method of claim 12, wherein generating the signal to noise power ratio comprises:
generating, using a first power accumulator, a signal power based at least in part on the recovered signal;
generating, using a second power accumulator, a noise power based at least in part on the noise signal; and
generating the signal to noise power ratio based at least in part on the signal power and the noise power.

16. The method of claim 12, wherein generating the noise signal comprises:
extracting, using a notch infinite impulse response (IIR) filter, the noise signal from the output signal.

17. A system comprising:
a device under testing (DUT); and
a controller, wherein the controller is configured to:
receive, based at least in part on an input signal, an output signal from the DUT;
generate a noise signal based at least in part on the input signal and the output signal;
generate a recovered signal based at least in part on the output signal and the noise signal;
generate a signal to noise power ratio based at least in part on the recovered signal and the noise signal; and
generate a performance metric for the DUT based at least in part on a comparison between the signal to noise power ratio and a predetermined power threshold.

18. The system of claim 17, wherein the DUT is a continuous-time sigma-delta analog to digital converter.

19. The system of claim 17, wherein the input signal is a sinusoid and the controller is further configured to generate the input signal by at least:
generating a modulated pulse; and
filtering the modulated pulse to generate the sinusoid.

20. The system of claim 17, wherein the system is a system on a chip (SoC) or a system in a package (SiP).
